(19) United States
(12) Patent Application Publication
(10) Pub. No.: US 2007/0201373 A1
(43) Pub. Date: Aug. 30, 2007

(54) Portable interactive apparatus and method for providing service information

(76) Inventor: Frank John Williams, Los Alamitos, CA (US)

Correspondence Address: Frank John Williams, 2711 Saint Albans Dr., Los Alamitos, CA, 90720, US

(21) Appl. No.: 11/703,305

(22) Filed: Feb. 5, 2007

Related U.S. Application Data
(60) Provisional application No. 60/764,931, filed on Feb. 3, 2006.
(60) Provisional application No. 60/780,473, filed on Mar. 8, 2006.

(51) Int. Cl. H04L 12/26; G08C 15/00; G06F 11/00; G01R 31/08; H04L 1/00; H04J 3/14; H04J 1/16

(52) U.S. Cl. 370/241

(57) ABSTRACT

A portable apparatus and methods for demonstrating and/or providing service information of an apparatus, such a displaying a movie demonstrating a service procedure and providing access to other associative type information of the apparatus and/or service procedure such as parts information and/or another movie demonstrating a service procedure of an unfortunate event possibly encountered by a viewer while performing the first service procedure being demonstrated.

### RELATED APPLICATIONS

This application claims the benefit of: provisional patent application Ser. No. 60/764,931 filed Feb. 3, 2006, and provisional patent application 60/780,473 filed Mar. 8, 2006 by the present inventor

### BACKGROUND

1. Field of the Present Disclosure

This disclosure relates to an apparatus and method of operation for providing service information of an apparatus. More specifically, an interactive apparatus and method for providing at least one of a: image demonstrating a service procedure of an apparatus, information of an apparatus, protocols of an apparatus, information of a part of an apparatus, ordering a part of the apparatus, interaction with content of a service procedure of an apparatus.

2. Description of the Related Art

Because the growth of commerce and the evolution of the modern machine, service procedures to keep the equipment running and functional has become an imperative necessity to every business and household. The modernization of the apparatus implies that many service procedures also had to evolve into elaborate and complex methodologies. As a consequence, the extensive amounts of information and/or parts required to ensure for a successful service procedure now depends on many factors such as: the apparatus, available technical information, the procedure, technical experience, technical expertise, parts, events, possible unfortunate events encountered during the procedure, and others to name a few.

Recently, movies have embarked in the difficult process of providing the rich and detailing technical information necessary and/or associated to the different service procedures. But unfortunately, because of the complexity of the procedures, movies lacking the ability to interact with the viewers, such as technicians and end-users, can not offer or address solutions to the particular circumstances, unfortunate events, and/or demands for information that each and every viewer may experience in an individual basis. On the other hand, an interactive movie offering a moderate level of interactivity, can potentially handle the distribution of information of some service procedures; but unfortunately, not without first incurring some sacrifices. This is because the interactivity in this type of movie is achieved through the display. In other words, the area wherein the important and valuable information is being provided must be utilized, such as introducing an image or shape for identifying another movie, thus sacrificing and diminishing the field of view and its intended means for information. More importantly, is that both of these movie types (passive and interactive) are associated to smart information means, such as a computer or a laptop, which are limited to a dust-free, safe and sometimes spacious environment.

Recently, a new approach has being conceived intending to alleviate the inconveniences of technical or service information distribution. Patent application No. 60/764,931 filed Aug. 1, 2006 by the present inventor, discusses an information platform named “method for providing technical information of complex service procedures.” While the invention teaches how to build a platform or protocol for providing service information, the method lacks interactivity and presents all the service information at once, thus overwhelming and possibly confusing the viewer. In addition, the method fails to mention or to consider rugged display means unlike the ones disclosed in the patent application which utilize the display of a computer. Because of the nature, space, conditions, power limitation, and location wherein many service procedures take place, prohibits the implementation of such fragile displays and apparatuses. More over, a PDA, while still lacking of strong and impact resistant physical attributes, it utilizes much of its already small interface (input panel) to provide buttons already attributed to other functions and/or character not related to the service information or procedure(s), thus reducing and limiting its access to service information, and interactivity.

Recent intend to provide service information such as: U.S. Pat. No. 6,317,570 Uchida et al, U.S. Pat. No. 5,802,429 Yamashita, US patent application publication US 2004/0186598 A1 Tanaka, and U.S. Pat. No. 5,715,496 Sawada et al, disclose several apparatuses and methods of obtaining information directly from the apparatuses for intents of remote diagnosis, and possible equipment management. Unfortunately they all fail of providing repair information to the client, thus fixing the machine. In addition, U.S. Pat. No. 3,999,307 Tsuda et at, U.S. Pat. No. 5,914,914 Moran, U.S. Pat. No. 4,839,743 Best et al, U.S. Pat. No. 5,791,907 Ramshaw, describe other methods and apparatuses which fail to provide an interactive apparatus and display means for providing and demonstration service information of complex and elaborate procedures. In addition all prior art, fails to included parts and their prospective commercialization.

In view of the foregoing and shortcomings, the disclosed inventive apparatus and methods teaches away from the recently used and conceived apparatuses and methodologies, while solving felt needs and provides unappreciated advantages distinguishing it over the prior art by also providing heretofore additional unknown advantages as described in the following summary.

### SUMMARY

It is therefore the object of the present invention to teach a portable and interactive apparatus and method for providing and/or displaying service information (PIADSI), such as demonstrating a service procedure, and any relevant, additional, and/or circumstantial information concerning or associated to a service procedure of an apparatus. In such fashion, a viewer can quickly, objectively, and affordably access important servicing information, without limitations of servicing environment, and displaying means. Optionally, the apparatus and method comprises the further ability to provide additional communication and recording means, for communicating with remote support entities and capturing valuable filed data for further analysis and study. For example, a viewer can easily record a movie of a problem affecting his/her machine, such as a bracket in the engine of a jet fighter, for further study such as sending a copy of the file to a technical support department to aid on the repair or troubleshooting of the recorded apparatus. This disclosure teaches certain benefits in construction and use which give rise to the objectives described below.

A primary objective inherent in the above described method is to provide advantages not taught by the prior art;

Another objective is to provide for the demonstration of elaborate and complex procedures;

Another objective is to provide a service procedure demonstrating an unfortunate event;

Another objective is to provide an intuitive method for viewers to obtain service information;

Another objective is to diminished stress and tension experienced by the technician or end-user when performing service procedures;

Another objective is to avoid the speculation of service procedures upon an unfortunate event;

Another objective is to fulfill end-users' needs to service their own equipment;

Another objective is to standardize the quantity and quantity of technical information;

Another objective is to alleviate warranty related repairs and/or expenses;

Another objective is to provide manufacturers' with a more compelling and/or secure medium to distribute service information;

A further objective is to allow manufacturers and/or technical entities to quickly introduce, upgrade or add new service procedure information;

Another objective is to avoid the extrapolation of parts information;

A further objective is to eliminate the possibility of identifying and/or ordering incorrect parts not relating to the relevant service procedure;

A further objective is to increase the troubleshooting success rate of technicians and end-users alike;

A further objective is to provide recording means for a viewer to record and/or archive important information;

A further objective is to permit quick and effective communications between the viewer and a technical support entities for aid on service information, such as service procedures, and commenting on recorded service information originated by the viewer;

A further objective is to provide viewers with means for recording their own field service information and/or apparatus information;

Other features and advantages of the described apparatus and method of use will become apparent from the following more detailed description, taken in conjunction with the accompanying drawings, which illustrate, by way of example, the principles of the presently described apparatus and method of its use.

### BRIEF DESCRIPTION OF THE DRAWINGS

The accompanying drawings illustrate at least one of the best mode embodiments of the present inventive apparatus and method of use. In such drawings:

FIG. 1 illustrates a general non-limiting view of a PIADSI (Portable Interactive Apparatus for Demonstrating and/or providing Service Information);

FIG. 2 illustrates an exemplary parts' menu of a PIADSI;

FIG. 3 illustrates a non-limiting view of an exemplary PIADSI comprising interactive images;

FIG. 4 illustrates another non-limiting view of an exemplary PIADSI comprising several means to input and output information;

FIG. 5 illustrates another non-limiting view of an exemplary PIADSI comprising a keyboard and mouse pad;

FIG. 6 illustrates another non-limiting view of an exemplary PIADSI comprising peripherals with wireless capabilities;

FIG. 7 illustrates a non-limiting time flow chart of exemplary buttons and their service information in reference to a primary information such as a movie;

FIG. 8 illustrates another non-limiting time flow chart of a primary information and exemplary timelines of other service information and corresponding buttons;

FIG. 9 illustrates a non-limiting display of an exemplary PIADSI illustrating an interactive movie demanding a selective response from a viewer.

### DETAILED DESCRIPTION OF THE PREFERRED EMBODIMENT

The above described drawing figures illustrate the described Portable Interactive Apparatus for Demonstrating and/or providing Service Information (PIADSI), operating method and methods of use in at least one of its preferred, best mode embodiment, which is further defined in detail in the following description. Those having ordinary skill in the art may be able to make alterations and modifications what is described herein without departing from its spirit and scope. Therefore, it must be understood that what is illustrated is set forth only for the purposes of example and that it should not be taken as a limitation in the scope of the present apparatus and method of use.

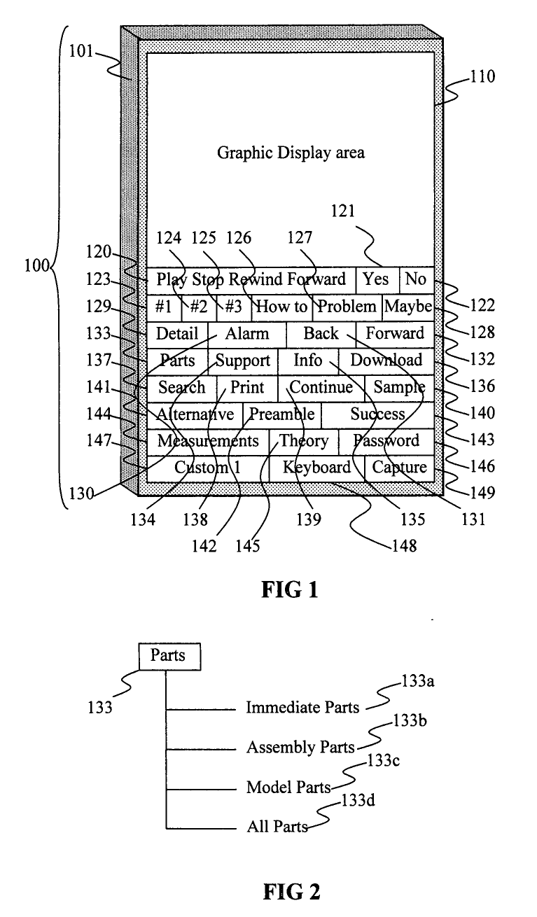

FIG. 1 illustrates a general non-limiting illustration of a Portable Interactive Apparatus for Demonstration and/or providing Service Information (PIADSI) 100 (FIG. 1). The display area 110 (FIG. 1) is wherein some or most of the service information is preferably displayed, for example a movie demonstrating a service procedure such as “replacing the rollers of a laser printer.” Several Input Elements, such as entry keys or push buttons are also illustrated. For example, the service information controls 120 (FIG. 1), are used to start, pause, stop, rewind, and forward the movie, slide show, and still images demonstrating the service procedure of the apparatus which is being displayed on the graphic display area 110 (FIG. 1). The “Yes” button 121 (FIG. 1) and the “No” button 122 (FIG. 1) are used to receive input from the viewer based on content of the service information (movie, slideshow, etc.). For example, the movie asks the viewer if the scanner light in his/her copier comes on during warm-up. The viewer can answer to the status of his/her copier's scanner light simply by pushing the “Yes” 121 (FIG. 1) or “No” 122 (FIG. 1) keys. Other input elements for “demands from content” are the exemplary “selective type,” buttons such as #1 123 (FIG. 1), #2 124 (FIG. 1), and #3 125 (FIG. 1); which are used to give the user the option to select and/or choose at least one of them in respond to information being displayed on graphic display area 110 (FIG. 1). For example, a movie demonstrating a viewer “how to replace the rollers of his laser printer,” displays two still images numbered 1 and 4 respectively, wherein each still image is illustrating worn rollers. Upon selecting the image that best matches the worn rollers in his/her printer, the viewer clicks the corresponding button, such as #1 123 (FIG. 1), leading the viewer to another movie per se, demonstrating service procedures associated to the type of worn experienced by the rollers of the printer. The button named “How to” 126 (FIG. 1) is used to identify other service information covering or addressing information not included in the primary service information. For example, the movie demonstrating the “printer's roller replacement” procedure mentions to remove the printer's cartridge, yet it never shows how to do it. While is true that most viewers know “how to remove the cartridge,” a new or occasional viewer probably does not know or remember. Therefore, the “How to” button 126 (FIG. 1) provides the new or occasional viewer imperative service information such as another movie demonstrating the removal of the cartridge; thus saving viewer's time and frustration, while it helps reducing the length of service procedures and respective movies, wherein the removal of the cartridge is a necessity. The button named “Problem” 127 (FIG. 1) is implemented to provide service information addressing any problem(s) possibly encountered while performing a service procedure being demonstrated. For example, the movie demonstrating the “replacement of the printer's rollers” shows how to remove the paper supply unit (cassette). However, when the viewer intends to remove the paper cassette as shown, he/she fails to do so. Clicking the “Problem” button 127 (FIG. 1) while the movie mentions the removal of the paper cassette, automatically provides another movie(s) describing additional procedures to remove the paper cassette being mentioned. In another example, clicking the “Problem” button 127 (FIG. 1) provides a list of names of movies that demonstrate possible problems encountered during a service procedure, such as the name “paper cassette can not be opened” for providing the respective movie. The key or button named “Maybe” 128 (FIG. 1) is used to by the viewer to respond with uncertainly to content from the service information. For example, a movie demonstrating the “roller replacement” asks if oil is present in the gears next to the rollers. In this particular moment, the viewer must answer “yes” or “no” in order to continue. Clicking the “Maybe” button 128 (FIG. 1) in this example, will display another service information such as another movie aimed to help the viewer decide if indeed oil is present in the neighboring gear and/or rollers. The key named “Detail” 129 (FIG. 1) provides the viewer more detailing service information, such as a zoom-in or zoom-out version of the content being illustrated. For example, the movie is showing a roller in the printer. By clicking the “Detail” button 129 (FIG. 1) the viewer can see a close-up slide show per se, of that particular region of the printer. The button named “Alarm” 130 (FIG. 1) identifies a “stop and/or wait for input” type function. For example, while the movie demonstrating the “replacement of the printer's rollers” is displayed, the “Alarm” button 130 (FIG. 1) starts blinking, and the movie is automatically paused. In other to continue, the viewer must click the “Alarm” button 130 (FIG. 1) resulting in a series of possibilities such as alarming information, protocols, and/or others. Optionally, only a few buttons and/or functions remain active wherein an “alarm” has developed such as allowing the viewer to rewind the movie per se. The “Back” button 131 (FIG. 1) and the “Forward” button 132 (FIG. 1) are navigational type buttons to browse and navigate between the different service information files being implemented. For example, a viewer watching a movie demonstrating a roller replacement clicks the “Detail” button 129 (FIG. 1). As a result, a new image is formed in the display 110 (FIG. 1) of the PIADSI 100 (FIG. 1) illustrating close up pictures of a particular section of the printer. By clicking the “Back” button 131 (FIG. 1), the viewer can return to the previous movie, and continue or re-start watching again the demonstration of the “replacement of the printer's rollers.” In similar fashion, clicking the “Forward” button 132 (FIG. 1) in this particular time, produces again the close up images associated to the “Detail” button at the time. The button named “Parts” 133 (FIG. 1) offers one of the most important service informational aids that the PIADSI is designed to provide. The “Parts” button 133 (FIG. 1) is used to provide parts' information and/or other type of information relative to such parts. For example, when the viewer opens a door in his/her printer as shown by a movie, he/she notices that his/her printer door is broken or damaged. Clicking the “Parts” button 133 (FIG. 1) provides the viewer with parts information such as diagrams, part numbers and/or prices. Optionally, it provides an ordering protocol to order or purchase parts such as that of the damaged door in the previous example. The “Support” button 134 (FIG. 1) allows the viewer to establish communications with technical support or other type of support entity. For example, the viewer recognizes the necessity to communicate or talk with technical support. Simply by clicking the “Support” button 134 (FIG. 1) opens a choice of mediums available to communicate and/or establish communications with support or other entities of choice. For example, open an electronic chat, to quickly text-message a support department for assistance. In another example, the “Support” button 134 (FIG. 1) accesses another computer capable to provide further support and/or service information. The button named “Info” 135 (FIG. 1) provides identifying information and other types of valuable information. For example, a viewer clicks the “Info” button 135 (FIG. 1) and a table is displayed providing information such as: the movie name and/or number, the length of the movie, the degree of service difficulty, etc. Another example is that in which the “Info” button 135 (FIG. 1) produces a menu including a “theory” link which leads to a movie per se, discussing the theory of operation of the elements of the apparatus involved in the service procedures being discussed. The “Download” button 136 (FIG. 1), allows the viewer to download or obtain additional information for the PIADSI. For example, the viewer can download a later version movie demonstrating the latest service procedures and/or information. The button named “Search” 137 (FIG. 1), is used to find particular information or section(s) of the media's content. For example, the viewer remembers that in the movie demonstrating the replacement roller service procedure, the host in the movie mentions a black bushing. Using the search feature under the “Search” button 137 (FIG. 1) the viewer can enters the words “black bushing,” and the search engine finds the portion in the video's sound track (or other), wherein the words “black bushing” is mentioned, thus pinpointing the location and/or other service information. The “Print” button 138 (FIG. 1) is used to print any available service information the viewer decides. For example, the viewer decides to print a slide or still image from the movie demonstrating a service procedure. Simply by clicking the “Print” button 138 (FIG. 1) a protocol appears allowing the viewer to print or save the slide or still image from the movie. The “Continue” button 139 (FIG. 1) allows the viewer to stop or pause the content on the PIADSI to be continue at a later time. For example, the viewer watching the demonstration of a roller replacement is interrupted. Clicking the “Continue” button 139 (FIG. 1) allows the viewer to proceed watching the demonstration at a later date or time. Optionally, a reminder protocol can be included or attached allowing the viewer to enter selections to be reminded and/or continue the service procedure(s). The “Sample” button 140 (FIG. 1) is for additional sampling service information, such as allowing the viewer to see further or more detailing samples. For example, the roller replacement procedure mentions and illustrates a bad roller. The viewer can activate the “Samples” button 140 (FIG. 1) to see further samples of bad rollers. In another sample, a movie demonstrating a service procedure mentions to click the “Samples” button 140 (FIG. 1) to view further images of worn parts per se. The “Alternative” button 141 (FIG. 1) is used to identify alternative service information such as other movies demonstrating alternative service procedures. For example, a viewer is watching a movie demonstrating a service procedure and notices that rollers of his/her printer are damaged and need immediate replacement. However, such rollers are not at hand. Simply by clicking the “Alternative” button 141 (FIG. 1), the viewer is provided with emergency or alternative procedures demonstrating what to do temporarily or how to clean the roller temporarily in order to resume temporary functional status of the apparatus (printer). In another example, a movie mentions of additional ways to remove a part of the apparatus, which are found under the “Alternative” button 141 (FIG. 1). The “Preamble” button 142 (FIG. 1) provides a small and brief re-enactment(s) of the service procedure(s), thus allowing the viewer to acknowledge the major steps involved. For example, a viewer would like to know the major parts and/or actions involve in the “roller replacement” service procedure. Simply by clicking the “Preamble” button 142 (FIG. 1), the viewer can see the parts involved and a discussion of the major steps involved in replacing the rollers. Suggestively, the viewer can decide to proceed with the service replacement procedure or stop. In another example, the viewer clicks on the “Preamble” button 142 (FIG. 1) to remember or overview the steps involved of a particular service procedure. The “Success” button 143 (FIG. 1) is used to simply finish the service event. For example, the viewer has successfully completed and/or followed all the service procedures demonstrated by the PIADSI and clicks the “Success” button 143 (FIG. 1) to end and turn off the PIADSI. The “Measurements” button 144 (FIG. 1) responsible for displaying a database of particular values, such as the adjusting gaps or distances of solenoids, standard or recommended pressures values, etc. For example, a viewer replacing a solenoid can quickly access information regarding the distances of other solenoids in the immediate neighborhood, simply by clicking the “Measurements” button 144 (FIG. 1). The “Theory” button 145 (FIG. 1) which its function was just described as part of the “Info” button 135 (FIG. 1) above, is to produce information of theory in the apparatus or other. Noteworthy, this example quickly illustrates how particular buttons and/or respective functions, can indeed by associated to others, named differently, repeated and/or be incorporated as part of other functions, menus, sub-menus, etc. thus demonstrating the variety of function, elements, and associations that are possible. Returning to FIG. 1, the button labeled “Password” 171 (FIG. 1) allows the viewer to access the service information contained and/or displayed by the PIADSI. For example, in a military application, the service information describing “how to adjust the doors of the missile bay” of a jet fighter is considered top-secret. Only personal with passwords can view or access the service information on the PIADSI. Optionally, the service information displayed by the PIADSI is encrypted to at least one of a: PIADSI, password(s) and/or any other type information, physical items, permissions, and security keys. The “Custom 1” button 147 (FIG. 1) is used to illustrate a modifying or modifiable type button and respective service information. Means for displaying such as an OLED display can be incorporated by the PIADSI in an effort to provide buttons capable of changing their names and/or respective functions. For example, A PIADSI in English can be converted to Spanish and vice versa. In another example, particular and important information of a particular service procedure, could easily find a way to be identified in the keyboard of the PIADSI among other standard named buttons. In fact a PIADSI and/or any other type of apparatus comprising custom type buttons could be used to manage the demands and information terminologies of several service industries. For example, a cell phone can easily be adapted to operate as a PIADSI either temporarily or permanently. Another sample is that in which the “Custom 1” button 147 (FIG. 1) can be physically replaced with another button to establish a standard or other information access in the PIADSI to better fit a particular industry and/or viewer. The “keyboard” button 148 (FIG. 1) can provide access to implement many of the buttons of the PIADSI as letters to entry or type messages or information. In another example, clicking the keyboard button 148 (FIG. 1) displays keyboard on the display 110 (FIG. 1) allowing the viewer to select or even click a character for entry. The “Capture” button is used to allow input of other types of information and/or means for information such as a video camera. For example, the viewer can use the PIADSI to record images and/or sound that can later be share or reviewed by other entity such as a technical support personal. In another example the viewer records a sound of the apparatus, and uploads the file to an internet site allowing a technician which is miles away, to listen and share information, hopefully recognizing its origin to help the viewer to quickly address the abnormality if any.

FIG. 2 illustrates a non-limiting example of a parts menu of an exemplary PIADSI. The parts button 133 (FIG. 2) provides a parts menu comprising of several types of parts information associated to the service procedures and/or the apparatus. In addition, optional service information such as a shopping cart (parts ordering protocol) can generated valuable commercial applications for many entities, such as the viewer, the providers of the PIADSI, the providers of content for the PIADSI, and/or third parties. The “Immediate Parts” 133a (FIG. 2), provides information of only those parts immediately involved in the service procedure. Furthermore, it optionally provides a print and/or save function to quickly identify such parts at a later time. For example, a viewer watching a movie demonstrating a service procedure of how to replace the roller in a printer, clicks the “Immediate Parts” button 133a (FIG. 2), causing the movie to pause and to display parts information such as the part number of the rollers described in the movie. The “Assembly Parts” 133b (FIG. 2) provides the viewer parts diagrams of the assemblies and/or all the individual parts included on all the assemblies involved in the service procedure. For example, a viewer watching the roller replacement movie clicks the “Assembly Parts” 133b (FIG. 2) to see all the assemblies and/or all parts from the assemblies with their respective part numbers, that are involved in the service procedure such as the paper feed unit, rollers, shafts, clutches, bushings, springs, etc. It could also provide a “save to” function that the viewer can see later when ordering parts. In another example, clicking the “Assembly Parts” 133b (FIG. 2) simply provides a list of the pages wherein such parts are in the parts' manuals, thus permitting the viewer to quickly allocated parts information on a physical manual per se. The “Model Parts” 133c (FIG. 2) provides information of all the parts comprising the apparatus. For example, when the viewer clicks the “Model Parts” 157c (FIG. 2), parts diagrams including all the parts and assemblies of the apparatus are provided, thus allowing the viewer see parts information of assemblies or other sections of the machine not included by the movie demonstrating the service procedure. In addition, a shopping cart allows the viewer to quickly order a selected part for his/her apparatus. The “All Parts” 133d (FIG. 2) provides access to parts information of several apparatuses. For example, the viewer clicks the “All Parts” option 133d (FIG. 2) and menus appear allowing the client to choose a type of machine and manufacturer of choice, such as Canon printers, Canon copiers, HP printers, and Xerox printers.

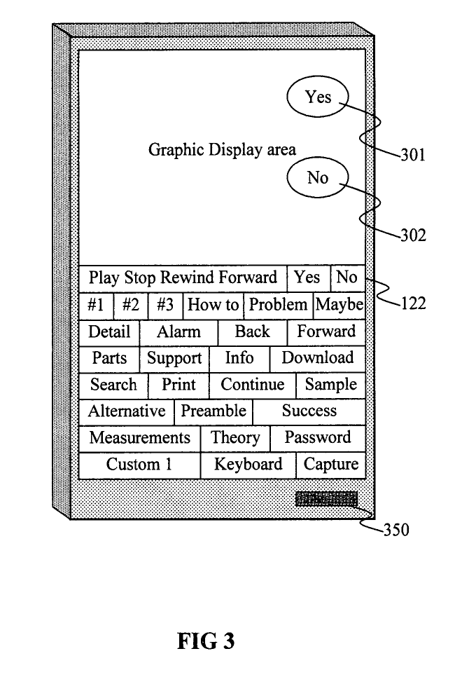

FIG. 3 illustrates another non-limiting example of a PIADSI, this time comprising an interactive movie illustrating interactive images and other interactive entry as well. Clicking the “Yes” image 301 (FIG. 3) responds positively to the content from the movie. In similar fashion, the “No” image 302 (FIG. 3) can interact with the movie's content. In addition, the “No” image 302 (FIG. 3) could have a similar function to the “No” button 122 (FIG. 3), therefore exemplifying that a PIADSI could objectively permit interactive service information from the display as well as interactive service information from the buttons. The microphone 350 (FIG. 3) can also be used to allow speech entry, such as saying the word “no” instead and/or additional to the “No” button 122 (FIG. 3) and/or additional to the “No” image 302 (FIG. 3).

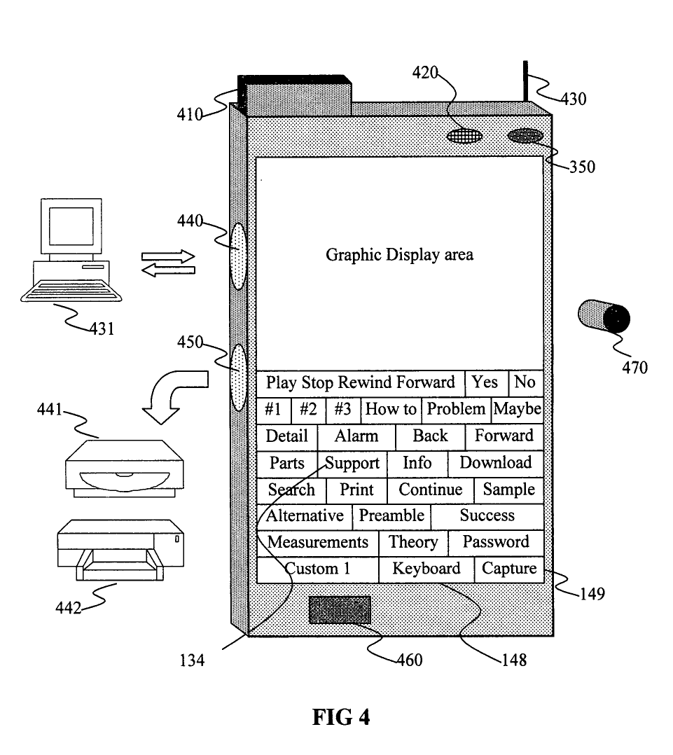

FIG. 4 illustrates a non-limiting view of a PIADSI comprising several optional inputs and optional outputs. A Camera 410 (FIG. 4) is provided for recording at least one of a: still images, sound files, and video. Thus allowing the viewer to record important field and apparatus information that suggestively could be used to be analyzed or reviewed by others. For example, a viewer clicks the “capture” button 149 (FIG. 4) to record a video of a problem occurring in a machine, redisplayed the just recorded movie in the display area 110 (FIG. 4) and later send it to a support entity to be analyzed in an effort to aid troubleshooting the apparatus. The speaker 420 (FIG. 4) provides sound reproduction means. For example, the viewer can reanalyze a recorded sound. The microphone 350 (FIG. 4) permits sound recording means. The antenna 430 (FIG. 4) is used for radio or alike type communication such as permitting for cell phone capabilities and/or the downloading of a telephonic type movie per se. The port 440 (FIG. 4) is used to transfer data, such as downloading information from a computer 431 (FIG. 4), another PIADSI and/or any other information providing system. The port 450 (FIG. 4) is for sending information to peripherals such as copying a recorded movie into a disc burner 441 (FIG. 4) and/or print an image into a printer 442 (FIG. 4). The mouse pad 460 (FIG. 4) is for controlling a pointer on the graphic display area 110 (FIG. 4). The laser light pointer 470 (FIG. 4) in this example is to be adapted or to be used in conjunction with the PIADSI, thus allowing to generate a laser beam or other for concentrating effort on a specific element or area of an image of an apparatus. For example, a movie is recorded by the PIADSI wherein the laser beam was used to “highlight” a part to aid technical support to better identify the issue or part in the movie.

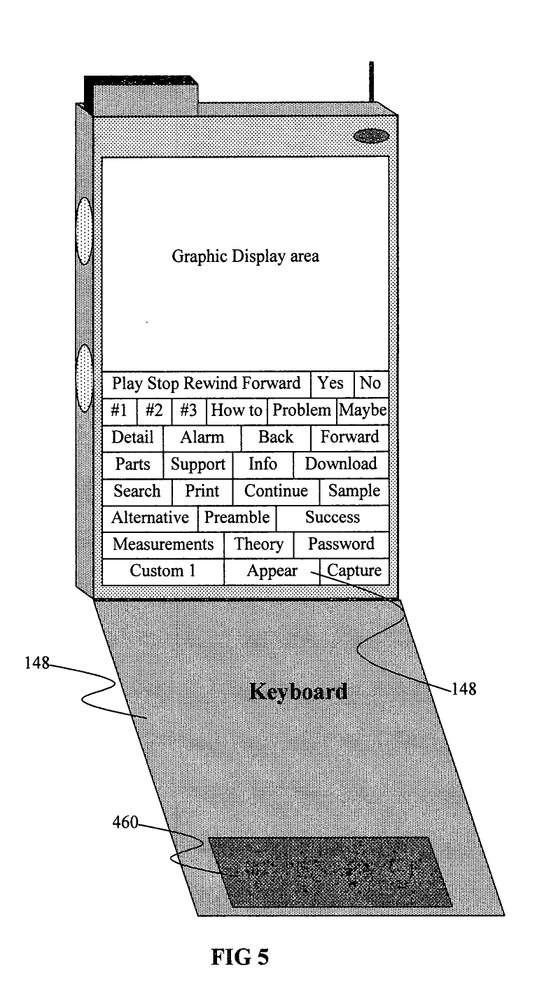

FIG. 5 illustrates another non-limiting view of an exemplary PIADSI including a keyboard 500 (FIG. 5) and a mouse pad 460 (FIG. 5). In this sample, the keyboard 500 (FIG. 5) is attached to the PIADSI via a hinge allowing it to be flipped or fold.

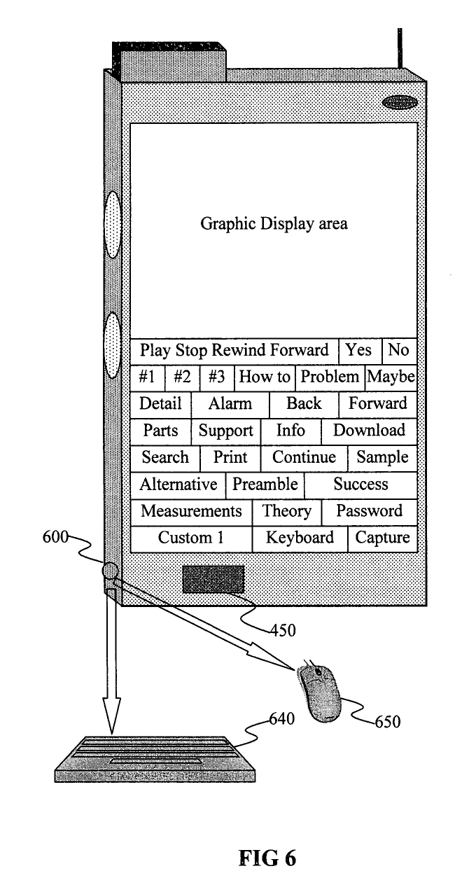

FIG. 6 illustrates an exemplary PIADSI and some wireless peripherals. The wireless communications port and/or means 600 (FIG. 6) communicates with the wireless keyboard 640 (FIG. 6) and the wireless mouse 650 (FIG. 6). The joystick or mouse pad 450 (FIG. 6) is overruled when the wireless mouse 650 (FIG. 6) or other is implemented.

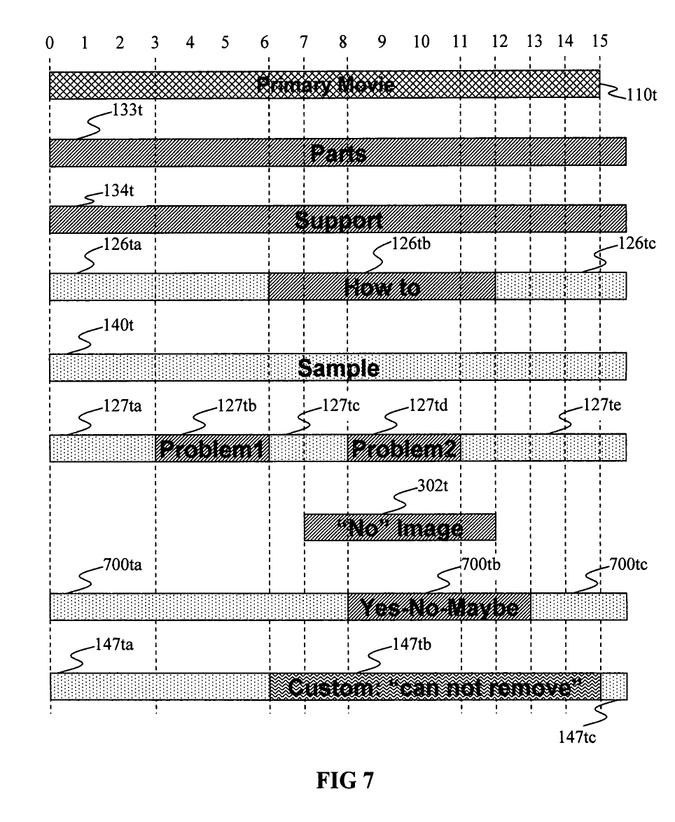

FIG. 7 illustrates the timelines of several buttons and/or associated exemplary service information(s). For example, the timeline of a primary movie 110t ( FIG. 7) demonstrating a service procedure is illustrated lasting a total of 15 seconds. The timelines of additional service information comprising information associated to the service procedure illustrated by the movie 110t (FIG. 7) are shown below the movie's timeline. As shown, the “Parts” timeline 133t (FIG. 7) indicates that accessibility to parts information of the service procedure in the movie is available for more than 15 seconds or the full time lapse of the primary movie. The “Support” timeline 134t (FIG. 7) indicates that support information and/or protocols are available at all times during the movie (exceeding 15 seconds). On the other hand, the “How to” function associated to the “How to” button is available only for a few seconds of the movie. When the movie begins, the first portion of the “How to” timeline 126ta (FIG. 7) indicates that information is not available. The, on the sixth second, the second portion of the “How to” timeline 126tb (FIG. 7) indicates that its information is available but only for a total of six more seconds. On the twelve second, the third portion of the “How to” timeline 126tc (FIG. 7) indicates that its information is no longer available. The “Sample” timeline 140t (FIG. 7) illustrates that information associated to the “Sample” button and therefore any sampling information is never available during the primary movie 110t (FIG. 7). The first portion of the “Problem” timeline 127ta (FIG. 7) indicates that information is not available. In the second portion, the “Problem” timeline 127tb (FIG. 7) indicates that problem information such as movie is available for a period of 3 seconds. In the third time portion (beginning on the 6^{th} second), the “Problem” timeline 127tc (FIG. 7) indicates that information for the “problem” button is not available for a period of 2 seconds. On the fourth time portion (beginning on the 8^{th} second), the “Problem” timeline 127td (FIG. 7) indicates that information such as a different movie demonstrating a completely different problem procedure is available for 3 seconds. In the fifth portion (beginning on the 11^{th} second) no more information is again available during the remaining part of the movie 110t (FIG. 7). The “No” image timeline 302t (FIG. 5) appears on the display in the 7^{th} second indicating that an interactive type movie awaits or allows a “No” type answer from the viewer. If the viewer clicks the “No” image on the display it provides other service information, such as another movie addressing the “no” type input situation selected from the viewer. The Yes, No and/or Maybe timeline illustrates that only for a few seconds the respective buttons permit and/or react to an entry. For example, 700ta (FIG. 7) implies that neither of the buttons even when pushed will produce any type of response or information. However, on the 8^{th} second, the timeline 700tb (FIG. 7) indicates that all three buttons allow entry, to produce their respective outcomes and/or information(s). Once again, starting the 13^{th} second, the timeline 700tc (FIG. 7) indicates that all buttons become inoperative again. The next timeline illustrates the availability and activity of a custom type button. The timeline 147ta (FIG. 7) indicates that no name and no accessibility is present in the custom type button. Then, in the 6^{th} second, the button displays the name of: “can not remove” and its timeline 147tb (FIG. 7) indicates that if the viewer pushes the button, information relating to “not been able to remove a part, etc.” is provided. Then, on the 5^{th} second, the timeline 147tc (FIG. 7) indicates that the name on the button disappears and so it does its functionality too.

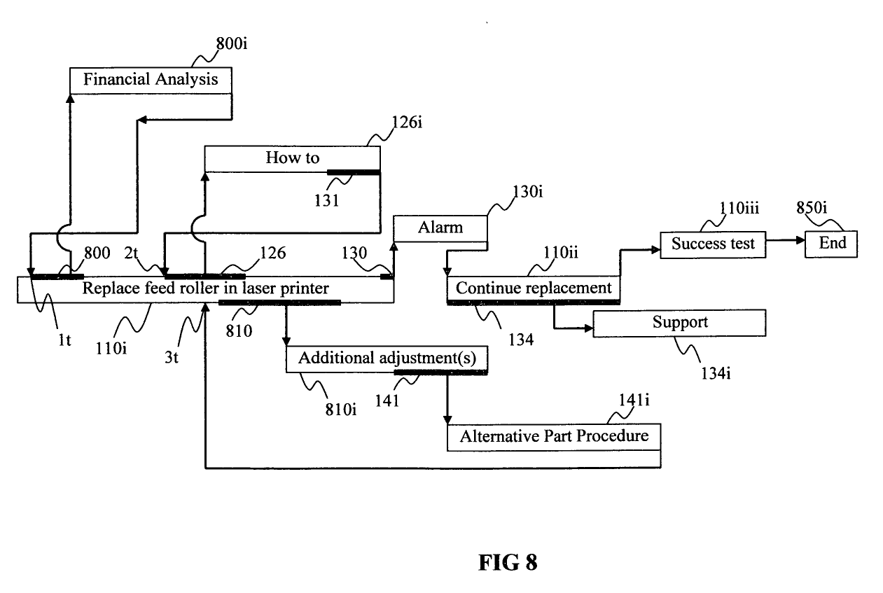

FIG. 8 illustrates a non-limiting timeline flow chart of some sample keys of an exemplary PIADSI. The timeline of the primary service information 110i (FIG. 6) illustrates the timelines of four buttons such as the “Financial Analysis” button 800 (FIG. 8), the “How to” button 126 (FIG. 8), the “Additional Adjustments” button 810 (FIG. 8), and the “Alarm” button 130 (FIG. 8). When the “Financial Analysis” button 800 (FIG. 8) is pushed or activated, the “Financial Analysis” information 800i (FIG. 8) is provided, such as a movie discussing the operating cost of the present apparatus and/or a new apparatus. After 800i (FIG. 8) is delivered, the viewer is returned automatically to a point 1t (FIG. 8) in the timeline of the primary service information 110i (FIG. 8). Activation of the “How to” button 126 (FIG. 8) produces the “How to Information” 126i (FIG. 8), such as another movie demonstrating how to remove the roller of a printer. Before the “How to Information” 126i (FIG. 8) is finished, the diagram illustrates a “Back” button 131 (FIG. 8), that when pushed, returns the viewer back to another point in time 2t (FIG. 8) of the primary service information 110i (FIG. 8). Activating of the “Additional adjustments” button 810 (FIG. 8) provides the viewer the “Additional adjustment” information 810i (FIG. 8), such as a slideshow demonstrating adjustment of a solenoid in the immediate area of the service procedure being demonstrated by the primary service information 110i (FIG. 8). After delivering approximately 50% of the content of the “Additional adjustments” information 810i (FIG. 8), the “Alternative procedure” button 141 (FIG. 8) of the PIADSI allows for the “Alternative Part Procedure” information 141i (FIG. 8) that after being delivered, returns the viewer to the point in time 3t (FIG. 8) of the primary service information 110i (FIG. 8). Towards the end of the “replace feed roller in laser printer” procedure or primary service information 110i (FIG. 8), the “Alarm” button 130 (FIG. 8) begins flashing (or other) warning the viewer, but also stopping the demonstration of the procedure. At this point, the viewer must click the “Alarm” button 130 (FIG. 8) in order to proceed or continue with the demonstration of the procedure. Clicking of the “Alarm” button 130 (FIG. 8) delivers the “alarm” information 130i (FIG. 8) that after being delivered, automatically continues with the “continue replacement” information 110ii (FIG. 8). FIG. 8 also illustrates that during the “continue replacement” information 110ii (FIG. 8) the “Support” button 134 (FIG. 8) is available. Clicking the “Support” button 134 (FIG. 8) begins the “Support” information 134i (FIG. 8) such as a contact protocol to connect the viewer with a technical support entity like a person or even another computer. After completing the observation of the “Continue replacement” information 110ii (FIG. 8), the “Success test” information 110iii (FIG. 8) is automatically provided, such as a demonstrating a protocol to inspect the apparatus and its operation. Finally, the “end” information 850i (FIG. 8) is provided, such as a protocol requesting viewer comments and information about their service experience.

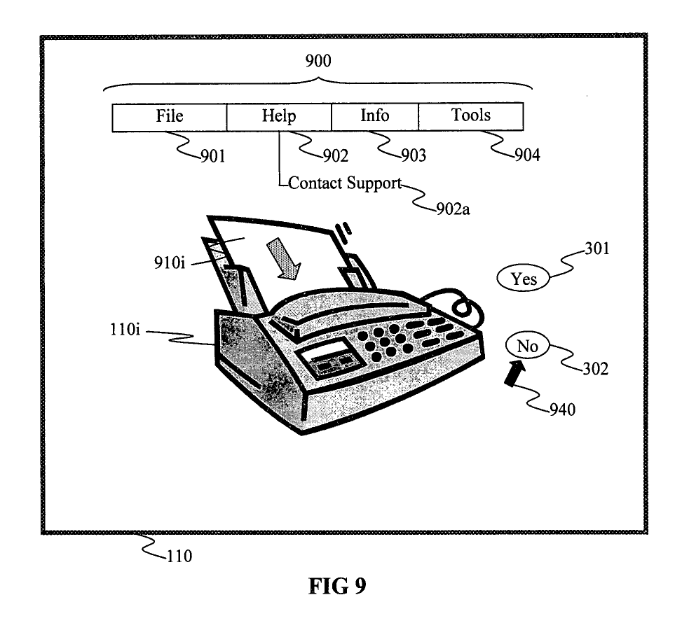

FIG. 9 illustrates a display of a PIADSI. The screen or display 110 (FIG. 9) illustrates a toolbar 900 (FIG. 9) and some menus such as the “File” menu 901 (FIG. 9), the “Help” menu 902 (FIG. 9), the “Info” menu 903 (FIG. 9) and the “Tool” menu 904 (FIG. 9). Also being displayed is the “Contact support” submenu 902a (FIG. 9) which in this example is part of the “Help” menu 902 (FIG. 9). The information image 110i (FIG. 9), in this example, is a movie of a fax machine showing an original document 910i (FIG. 9) moving through the scanner of the fax. The first interactive displayed image, the “Yes” image 301 (FIG. 9) identifies a prospective “Yes” type response from the viewer. The second interactive image, the “No” image 302 (FIG. 9) identifies a “No” type response from the viewer. For example, the movie of the fax machine 110i (FIG. 9) asks the viewer if the original in his/her machine moves in identical fashion to the original 910i (FIG. 9) displayed in the movie. In this example, the viewer finds that his/her fax moves the document differently, thus allowing the viewer to answer “No” by using the pointer 940 (FIG. 9) and moving it over the interactive image named “No” 302 (FIG. 9) to click it, thus inputting a “No” type answer. Accordingly, service information respective to a “No” type answer is later displayed by the PIADSI.

Noteworthy, several types of service information can be incorporated and/or modified to provide a viewer complete and relevant service information upon demand and/or when necessary. For example, the disclosed patent application and apparatus does not mention a modular type memory, such as allowing the PIADSI to only received service information via means of the modular type memory. In this case, other behaviors and/or protocols can be and/or should be incorporated by the PIADSI. Another example is that in which the service information is provided by the display means of the apparatus, when a PIADSI is connected therein. Further methodologies and functions can be incorporated into the inventive apparatus of this disclosure, without departing from its spirit of providing a portable means for accessing service information, preferable movies and slide shows.

The enablements described in detail above are considered novel over the prior art of record and are considered critical to the operation of at least one aspect of the method of use and to the achievement of the above described objectives. The words used in this specification to describe the instant embodiments are to be understood not only in the sense of their commonly defined meanings, but to include by special definition in this specification: structure, material or acts beyond the scope of the commonly defined meanings. Thus if an element can be understood in the context of this specification as including more than one meaning, then its use must be understood as being generic to all possible meanings supported by the specification and by the word or words describing the element.

The definitions of the words or drawing elements described herein are meant to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements described and its various embodiments or that a single element may be substituted for two or more elements in a claim.

Changes from the claimed subject matter as viewed by a person with ordinary skill in the art, now known or later devised, are expressly contemplated as being equivalents within the scope intended and its various embodiments. Therefore, obvious substitutions now or later known to one with ordinary skill in the art are defined to be within the scope of the defined elements. This disclosure is thus meant to be understood to include what is specifically illustrated and described above, what is conceptually equivalent, what can be obviously substituted, and also what incorporates the essential ideas.

The scope of this description is to be interpreted only in conjunction with the appended claims and it is made clear, here, that each named inventor believes that the claimed subject matter is what is intended to be patented.

### Conclusion

From the present disclosed inventive method, it can be appreciated a novel portable apparatus, method and method of use for providing service information of an apparatus, such as a movie demonstrating a service procedure, and parts information of a service procedure. In addition, the apparatus can provide information on remote, hard to access, and rugged locations, which do not permit fragile information apparatuses such a computer, a laptop or even a PDA. Optionally, the apparatus provides means for recording information in the field regarding an apparatus for further study, analysis and/or consideration.

1. An apparatus for providing an Interactive interface for demonstrating a service procedure of an apparatus, the apparatus comprising:
a) A display means for displaying a primary service information, wherein said service information comprises at least one of a: service procedure of an apparatus, and part of and apparatus
b) An interactive element, such as button associated to at least one second service information of said apparatus
c) A store means for storing at least one of a said: first service information, and said second service information
d) Means for identifying an input from at least one said button
e) Implementing said display means for displaying said second service information.
